(19) United States
(12) Patent Application Publication
(10) Pub. No.: US 2007/0176808 A1
(43) Pub. Date: Aug. 2, 2007

(54) Switching power source device of multi-output type

(75) Inventor: Shohei Osaka, Niiza-shi (JP)

Correspondence Address: BACHMAN & LAPOINTE, P.C., 900 CHAPEL STREET, SUITE 1201, NEW HAVEN, CT, 06510, US

(73) Assignee: Sanken Electric Co., Ltd.

(21) Appl. No.: 11/653,686

(22) Filed: Jan. 16, 2007

(30) Foreign Application Priority Data
Jan. 17, 2006 (JP) 2006-008855

(51) Int. Cl. H03M 1/00

(52) U.S. Cl. 341/136

(57) ABSTRACT

A switching power source device is provided which comprises a reactor 31 connected in a series circuit of a second secondary winding 2c of a transformer 2, a regulatory MOS-FET 18 and a second rectifying smoother 15; and an output controller 19 for controlling the on and off operation of regulatory MOS-FET 18 based on a voltage V_{O2} applied on a smoothing capacitor 14 of second rectifying smoother 15. Inductance in reactor 31 serves to restrict charging current flowing into smoothing capacitor 14 from second secondary winding 2c so as to clamp voltages induced on first and second secondary windings 2b and 2c of transformer 2 at voltage V_{O1} on smoothing capacitor 5 in first rectifying smoother 6. This allows first and second diode currents I_{D1} and I_{D2} to simultaneously flow respectively through first and second secondary windings 2b, 2c in order to reduce current concentration in either of first and second secondary windings 2b and 2c and reduce power loss incurred in each secondary output circuit.

### TECHNICAL FIELD

This invention relates to a switching power source device of multi-output type provided with two or more secondary output circuits.

### BACKGROUND OF THE INVENTION

Switching power source devices have conventionally and widely been used to convert DC input from DC power source into an electric power of high frequency supplied to a primary winding of a transformer through a switching element turned on and off, and then, reconvert the electric power into plural DC power outputs through a rectifying smoother connected to each of secondary windings of transformer. A prior art switching power source device for example shown in FIG. 5, comprises a primary winding 2a of a transformer 2 and a main MOS-FET 3 as a main switching element connected in series to a DC power source 1; a first rectifying smoother 6 which comprises a first output rectifying diode 4 and a first output smoothing capacitor 5 both connected between a first secondary winding 2b of transformer 2 and a first DC output terminals 7 and 8; a main control circuit 9 for controlling the on and off operation of main MOS-FET 3 based on a first DC output voltage V_{O1} issued from first output terminals 7 and 8 through first smoother 6; and a second rectifying smoother 15 which comprises a second output rectifying diode 13 and a second output smoothing capacitor 14 both connected between a second secondary winding 2c of transformer 2 and second DC output terminals 16 and 17. First and second secondary windings 2b and 2c of transformer 2 are electro-magnetically coupled in the opposite polarity to primary winding 2a so that first and second diodes 4 and 13 are biased in the adverse or deactivated direction when main MOS-FET 3 is turned on to store electric energy in transformer 2 with winding current running through primary winding 2a of transformer 2. To the contrary, when main MOS-FET 3 is turned off, first and second diodes 4 and 13 are biased in the forward or activated direction to release electric energy from transformer 2 through each of first and second secondary windings 2b and 2c. Main control circuit 9 comprises a normal power supply 10 for producing a reference voltage V_{R1} for controlling first output voltage V_{O1}; an error amplifier 11 for producing an error signal V_{E1}, the differential voltage between first output voltage V_{O1} between first output terminals 7 and 8 and reference voltage V_{R1} from normal power supply 10; and a PWM (pulse width modulation) controller 12 for supplying main drive signals V_{G1} to a gate terminal of main MOS-FET 3 while PWM controller 12 controls the on duty of main drive signals V_{G1} dependently on error signal V_{E1} from error amplifier 11.

In operation of the switching power source device of multi-output type shown in FIG. 5, main control circuit 9 produces main drive signals V_{G1} to gate terminal of main MOS-FET 3 which therefore is turned on and off to intermittently apply DC voltage E from DC power source 1 on primary winding 2a of transformer 2, thereby causing pulsatile voltages to appear on first and second secondary windings 2b and 2c. First smoother 6 commutates and smoothes pulsatile voltage from first secondary winding 2b to develop first output voltage V_{O1} between first output terminals 7 and 8. Also, second smoother 15 commutates and smoothes pulsatile voltage from second secondary winding 2c to develop a second DC output voltage V_{O2} between second output terminals 16 and 17.

Error amplifier 11 compares first output voltage V_{O1} between first output terminals 7 and 8 with reference voltage V_{R1} of normal power supply 10 to produce an error signal V_{E1} to PWM controller 12 which controls the on duty, namely ratio of on to off time of main MOS-FET 3 by varying pulse width of main drive signals V_{G1} based on voltage level of error signals V_{E1}. Control of the on duty in main drive signals V_{G1} to main MOS-FET 3 causes variation in RMS (root-mean-square) value of electric current flowing through primary winding 2a of transformer 2 to change energy amount transmitted from the primary to the secondary side of transformer 2. Accordingly, restoration action or reintegration is applied to first output voltage V_{O1} between first output terminals 7 and 8 so that restoration action promotes to return first output voltage V_{O1} to the original predetermined level in response to amount of change in transmitted energy through transformer 2. This stabilizes first output voltage V_{O1} at the predetermined level between first output terminals 7 and 8.

Meanwhile, second output voltage V_{O2} between second output terminals 16 and 17 is maintained at a substantially constant level if first output voltage V_{O1} between first output terminals 7 and 8 unless there is any change in electric load connected to first or second output terminals 7 and 8 or 16 and 17 or in voltage E of DC power source 1.

Although there occurs any change in electric load connected to first or second output terminals 7 and 8 or 16 and 17 or in voltage E of DC power source 1, it causes little fluctuation in level of first output voltage V_{O1} since first voltage V_{O1} is stabilized by feedback control of main control circuit 9. However, level of second output voltage V_{O2} ranges due to change in various external factors even though level of first output voltage V_{O1} becomes steady. The technical reasons for fluctuation in level of second output voltage V_{O2} are believed due to facts that there is not a completely close electromagnetic coupling of windings 2a, 2b and 2c in transformer 2, in other words, the coupling coefficient is not 1 and that voltage drop appears due to electric resistance inherent in each electric parts and electric current flowing therethrough. Accordingly, large change, if occurs, in voltage E of DC power source 1 or electric load unfavorably makes level of second output voltage V_{O2} unstable.

To solve the above problem, another switching power source device is proposed as shown in Japanese Patent Disclosure No. 55-139073, which comprises, as shown in FIG. 6, an output regulatory MOS-FET 18 as an output regulatory switching element connected between second diode 13 and second capacitor 14 shown in FIG. 5, and an output controller 19 connected between second output terminals 16 and 17 and regulatory MOS-FET 18 for controlling the on and off operation of regulatory MOS-FET 18 based on second output voltage V_{O2} between second output terminals 16 and 17. Output controller 19 comprises a second normal power supply 20 for producing a reference voltage V_{R2} to control second output voltage V_{O2}; a second error amplifier 21 for producing an error signal V_{E2}, the differential voltage between second output voltage V_{O2} between second output terminals 16 and 17 and reference voltage V_{R2} from second power supply 20; and a second PWM controller 22 activated by voltage V_{T22} induced on second secondary winding 2c of transformer 2 when main MOS-FET 3 is turned off for adjusting the on duty of drive signals VS₂ supplied to a gate terminal of regulatory MOS-FET 18 in response to error signal V_{E2} from second error amplifier 21.

In operation of the switching power source device of multi-output type shown in FIG. 6, second PWM controller 22 adjusts the on duty, namely ratio of on to off time of regulatory MOS-FET 18 based on second output voltage V_{O2} between second output terminals 16 and 17, to thereby control the time of electric current flowing from second secondary winding 2c of transformer 2 to second capacitor 14. Accordingly, regulatory MOS-FET 18 can serve to control with great accuracy second output voltage V_{O2} taken out from second output terminals 16 and 17 through second smoother 15. FIG. 7(A) to FIG. 7(D) indicate respectively time charts of electric current I_{Q1} flowing through main MOS-FET 3, voltage V_{Q1} between source and drain terminals of main MOS-FET 3, electric current flowing through second diode 13 and electric current I_{D1} flowing through first diode 4.

In the switching power source device shown in FIG. 6, when main MOS-FET 3 is in the off condition and regulatory MOS-FET 18 is in the on condition, energy accumulated in transformer 2 during the on period of main MOS-FET 3 is discharged from second secondary winding 2c as an electric current supplied to second smoother 15. When main MOS-FET 3 is in the off condition and regulatory MOS-FET 18 is in the off condition, regulatory MOS-FET 18 is kept in the off condition to interrupt between second diode 13 and second capacitor 14 in second smoother 15 so that energy stored in transformer 2 during the on period of main MOS-FET 3 is released from first secondary winding 2b as an electric current supplied to first smoother 6. At this time, voltages induced on first and second secondary windings 2b and 2c of transformer 2 respectively equal to sums: V_{FD1}+V_{O1} and V_{FE2}+V_{O2} of voltage drops: V_{FD1} and V_{FD2} in the forward direction across first and second capacitors 5 and 14 and charged voltages V_{O1} and V_{O2} in first and second capacitor 5 and 14 in first and second smoothers 6 and 15. In the switching power source device shown in FIG. 5, first and second output voltages V_{O1} and V_{O2} have substantially correlative relationship respectively with turn number N_{S1} and N_{S2} of first and second secondary windings 2b and 2c of transformer 2. Unlike this, in the switching power source device shown in FIG. 6, the on duty of regulatory MOS-FET 18 determines charged level of voltage in second capacitor 14 so that first and second secondary windings 2b and 2c of transformer 2 induce first and second output voltages V_{O1} and V_{O2} satisfactory for the inequality: (V_{O1}+V_{FD1})/N_{S1}≧(V_{O2}+V_{FD2})/N_{S2}

In the switching power source device of multi-output type shown in FIG. 6, when regulatory MOS-FET 18 is turned on, and second diode 13 is biased in the forward direction during the period of time from point t₁ to t₂ of FIG. 7, electric current I_{D2} flows through second diode 13 as shown in FIG. 7(C) while each voltage induced on first and second secondary windings 2b and 2c of transformer 2 is restricted or clamped at voltage on second capacitor 14 to bias first diode 4 in the adverse direction, thereby preventing electric current I_{D1} from flowing through first diode 4 as shown in FIG. 7(D). Then, when regulatory MOS-FET 18 is turned off at a point t₂ to stop flow of second diode current I_{D2} as shown in FIG. 7(C), each voltage induced on first and second secondary windings 2b and 2c of transformer 2 is restricted or clamped at voltage on first capacitor 5 to bias first diode 4 in the forward direction, and therefore, as shown in FIG. 7(D), first diode current is sent through first diode 4. In this way, during the period of time from point t₁ to t₄ for transmitting energy accumulated from the primary to the secondary side of transformer 2, electric currents do not simultaneously flow from first and second secondary windings 2b and 2c of transformer 2, but flow alternately and intensively on either of first and second secondary windings 2b and 2c. As a result, this arrangement disadvantageously needs to shorten the period of time for sending electric current through each of first and second secondary windings 2b and 2c of transformer 2, while the maximum value in first and second diode currents I_{D1} and I_{D2} is elevated by the shortened period of time for sending electric current, and thereby, it brings about increased ripple current and incurs increased power loss through each of first and second secondary windings 2b and 2c of transformer 2 and each of first and second diodes 4 and 13. Also, concurrently, ripple current undesirably increases noise and ripple voltage in each of DC output voltages V_{O1} and V_{O2.}

Accordingly, an object of the present invention is to provide a switching power source device of multi-output type capable of reducing current concentration in any of first and second secondary windings of a transformer. Another object of the present invention is to provide a switching power source device that can diminish power loss suffered in the secondary output circuit.

### SUMMARY OF THE INVENTION

The switching power source device according to the present invention, comprises a primary winding (2a) of a transformer (2) and a main switching element (3) connected in series to a DC power source (1); a first rectifying smoother (6) connected to a first secondary winding (2b) of transformer (2); a second rectifying smoother (15) connected to a second secondary winding (2c) of transformer (2); a main control circuit (9) for controlling the on and off operation of main switching element (3) based on first rectifying smoother (6); a regulatory switching element (18) connected between a smoothing capacitor (14) provided in second rectifying smoother (15) and second secondary winding (2c); a reactor (31) connected in a series circuit of second secondary winding (2c), regulatory switching element (18) and second rectifying smoother (15); and an output controller (19) for controlling the on and off operation of regulatory switching element (18) based on a voltage (V_{O2}) applied on smoothing capacitor (14) of second rectifying smoother (15) to accumulate electric energy in transformer (2) during the on period of main switching element (3) and take out first and second DC outputs from respectively first and second secondary windings (2b, 2c) through first and second rectifying smoothers (6, 15) during the off period of main switching element (3).

When output regulatory switching element (18) is turned on during the off period of main switching element (3), inductance in reactor (31) serves to restrict charging current flowing into smoothing capacitor (14) in second rectifying smoother (15) from second secondary winding (2c) of transformer (2) so as to clamp voltages induced on first and second secondary windings (2b, 2c) of transformer (2) at voltage (V_{O1}) on smoothing capacitor (5) in first rectifying smoother (6). This causes output rectifying element (4) in first rectifying smoother (6) to be biased in the forward direction to allow first and second diode currents (I_{D1}, I_{D2}) to simultaneously flow respectively through first and second secondary windings (2b, 2c) of transformer (2). Then, when output regulatory switching element (18) is turned off while main switching element (3) is kept off, flow of second diode current I_{D2} from second secondary winding (2c) of transformer (2) is stopped, but first diode current (I_{D1}) continues to flow from first secondary winding (2b). In either of the on and off conditions of output regulatory switching element (18), first diode current (I_{D1}) continues to flow from first secondary winding (2b) of transformer (2) into capacitor (5) or a first electric load during the period of time for transmitting energy from the primary to the secondary side of transformer (2) after main switching element (3) is turned off so as to reduce a maximum value of first diode current (I_{D1}) through first rectifying smoother (6) for descent in the RMS value of output current. This reduces current concentration in either of first and second secondary windings to thereby reduce power loss incurred in each secondary output circuit.

### BRIEF DESCRIPTION OF THE DRAWINGS

The above-mentioned and other objects and advantages of the present invention will be apparent from the following description in connection with preferred embodiments shown in the accompanying drawings wherein:

FIG. 1 is an electric circuit diagram showing a first embodiment of the switching power source device of multi-output type according to the present invention;

FIG. 2 is a waveform diagram showing a voltage and electric currents at selected locations in the circuit shown in FIG. 1;

FIG. 3 is an electric circuit diagram showing a second embodiment of the switching power source device of multi-output type according to the present invention;

FIG. 4 is an electric circuit diagram showing a third embodiment of the switching power source device of multi-output type according to the present invention;

FIG. 5 is a circuit diagram showing a prior art switching power source device of multi-output type;

FIG. 6 is a circuit diagram showing another prior art switching power source device of multi-output type provided with an output regulatory switching element;

FIG. 7 is a waveform diagram showing a voltage and electric currents at selected locations in the circuit shown in FIG. 6.

### BEST MODE FOR CARRYING OUT THE INVENTION

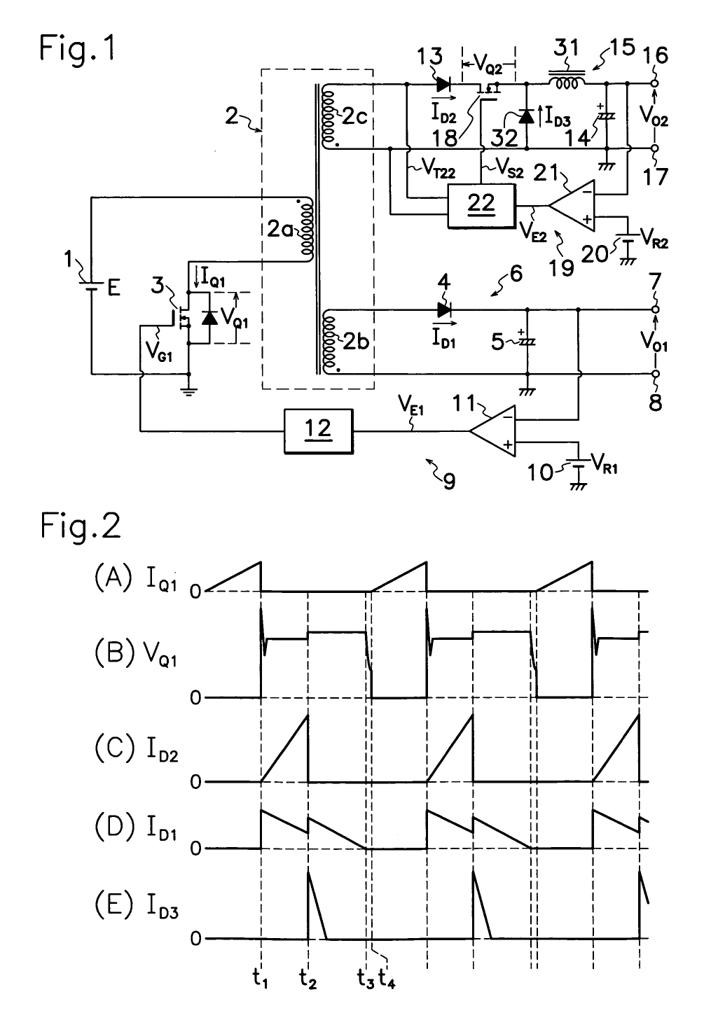

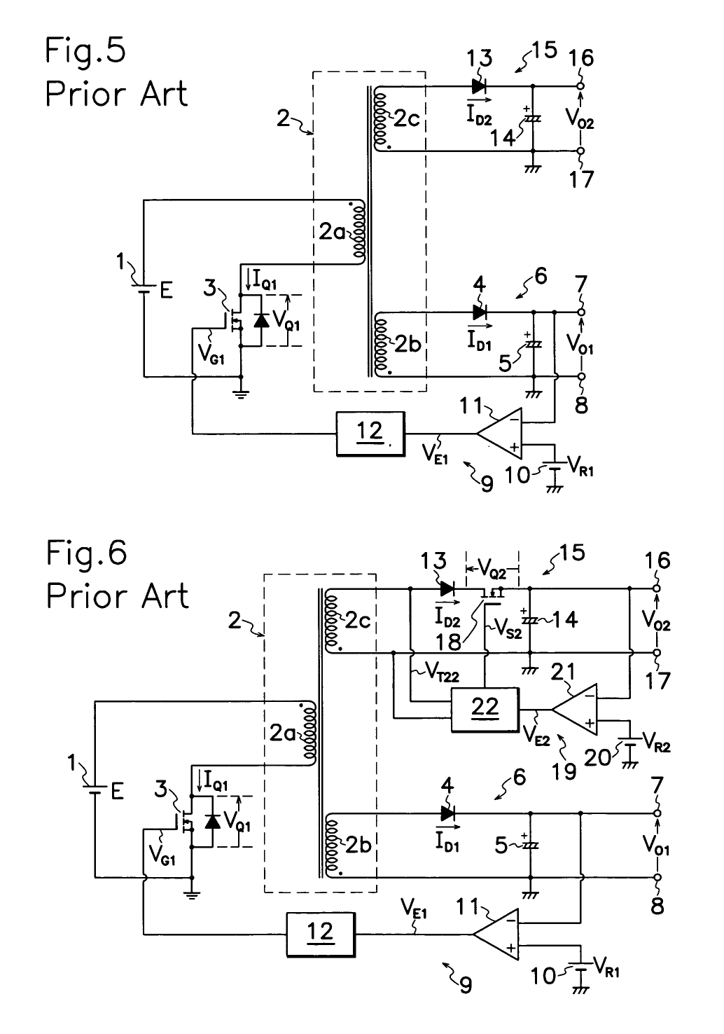

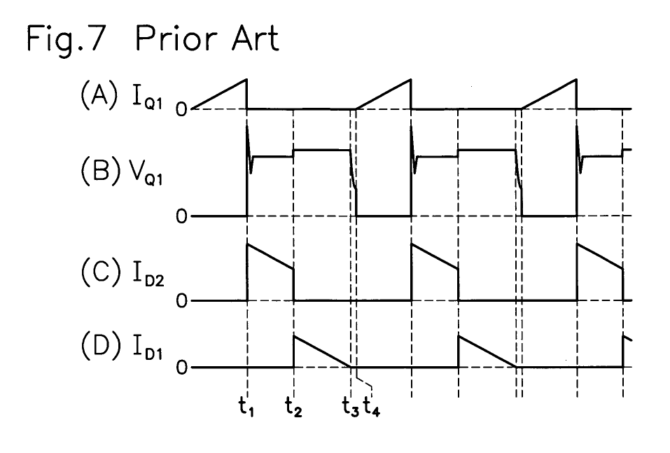

Embodiments of the switching power source device according to the present invention will be described hereinafter in connection with FIGS. 1 to 4 of the drawings. Same reference symbols as those shown in FIGS. 5 to 7 are applied to similar portions in FIGS. 1 to 4, omitting explanation thereon.

As shown in FIG. 1, the switching power source device according to a first embodiment of the present invention, comprises a reactor 31 for restricting electric current such as a choke coil connected between a source terminal of regulatory MOS-FET 18 and a high potential side (one end) of second capacitor 14; and a regenerative or recovery diode 32 as a recovery rectifying element connected between a junction of source terminal of regulatory MOS-FET 18 and reactor 31 and ground potential side (the other end) of second capacitor 14. Without limited to the connected location of reactor 31 shown in FIG. 1, reactor 31 may be connected to any location in a series circuit including second secondary winding 2c of transformer 2, second diode 13, regulatory MOS-FET 18 and second capacitor 14. Also, regulatory MOS-FET 18 is designed to be turned on when main MOS-FET 3 is turned off, and turned off when the on time is over which is determined by level of second output voltage V_{O2} between second output terminals 16 and 17. In detail, when level of second output voltage V_{O2} is lower than a target level, second PWM controller 22 extends the on time of regulatory MOS-FET 18 to boost second output voltage V_{O2}, however to the contrary, when level of second output voltage V_{O2} is higher than that the target value, second PWM controller 22 shortens the on time of regulatory MOS-FET 18 to diminish second output voltage V_{O2}. Configurations other than the foregoing are substantially similar to those in prior art switching power source device shown in FIG. 6.

In the arrangement shown in FIG. 1, when main MOS-FET 3 is in the on condition before a point t₁ of time, linearly increasing winding current I_{Q1} runs through a primary closed circuit including DC power source 1, primary winding 2a of transformer 2 and main MOS-FET 3 to accumulate electric energy in transformer 2. In this case, first secondary winding 2b of transformer 2 has a voltage induced in the opposite polarity to that in the primary side to bias first diode 4 in the adverse direction, thereby obstructing flow of first diode current I_{D1} through first diode 4 as shown in FIG. 2(D). At the same time, second secondary winding 2c has a voltage induced in the opposite polarity to that in the primary side to bias second diode 13 in the adverse direction, thereby obstructing flow of second diode current I_{D2} through second diode 13 as shown in FIG. 2(C).

When main MOS-FET 3 is turned off at point t₁, flow of winding current I_{Q1} in the primary closed circuit is stopped to clamp drain-source voltage V_{Q1} across main MOS-FET 3 at a sum voltage of supply voltage E from DC power source 1 and an additional voltage induced in primary winding 2a from the secondary side. At this moment, the polarity of each voltage induced in first and second secondary windings 2b and 2c of transformer 2 is turned over, and therefore, electric energy accumulated in transformer 2 is released by electric current flowing from each secondary winding 2b and 2c. Concurrently with this energy discharge, second PWM controller 22 of output controller 19 furnishes a drive signal V_{S2} of high voltage level to gate terminal of regulatory MOS-FET 18 to turn it on, and second diode 13 is biased in the forward direction so that second diode current I_{D2} starts flowing from second secondary winding 2c of transformer 2 through rectifying diode 13 to second capacitor 14, however, second diode current I_{D2} linearly and gradually increases from zero as shown in FIG. 2(C) under the restriction by inductance of reactor 31. Accordingly, charged second output voltage V_{O2} in second capacitor 14 progressively rises, but second output voltage V_{O2} is restricted to be below first output voltage V_{O1} on first capacitor 5 so as to clamp voltages derived in first and second secondary windings 2b and 2c of transformer 2 at the voltage V_{O1} on first capacitor 5. Simultaneously, applied on reactor 31 is the differential voltage between voltage V_{T22} on second secondary winding 2c of transformer 2 and charged voltage V_{O2} on second capacitor 14 of second smoother 15 to accumulate excitation energy in reactor 31.

When polarity of voltage induced in first secondary winding 2b of transformer 2 is turned over as mentioned above, first diode 4 is biased in the forward direction, first diode current I_{D1} flows from first secondary winding 2b through first diode 4 as shown in FIG. 2(D) along with second diode current I_{D2} flowing from second secondary winding 2c through second diode 13 as shown in FIG. 2(C).

Then, while main MOS-FET 3 is kept in the off condition, second PWM controller 22 of output controller 19 furnishes a control signal V_{S2} of low voltage level to gate terminal of regulatory MOS-FET 18 at point t₂ to turn it off and thereby cease second diode current I_{D2} through second secondary winding 2c of transformer 2 as shown in FIG. 2(C) while first diode current I_{D1} goes on flowing through first secondary winding 2b as shown in FIG. 2(D). Now, as excitation energy accumulated in reactor 31 during the on period of regulatory MOS-FET 18 is released due to linearly reducing third diode current I_{D3} of FIG. 2(E) flowing through regenerative diode 32, reactor 31, second capacitor 14 and second output terminals 16, 17 to electric load not shown. Then, accumulated energy has completely exhausted from transformer 2 at point t₃ so that first diode current I_{D1} through first diode 4 comes to substantially zero, and when time progress reaches time point t₄, main MOS-FET 3 is again turned on. The switching power source device of multi-output type performs basic operations including a feature or means for stabilizing first and second output voltages V_{O1} and V_{O2}, however, their description is herein omitted because they are essentially similar to those of prior art switching power source devices shown in FIGS. 5 and 6.

In the embodiment illustrated in FIG. 1, the switching power source device can reduce current concentration in second secondary winding 2c by virtue of coincidental first and second diode currents I_{D1} and I_{D2} through first and second secondary windings 2b and 2c of transformer 2 when regulatory MOS-FET 18 is turned on during the off period of main MOS-FET 3. Also, first diode current I_{D1} can conveniently successively flow through first secondary winding 2b of transformer 2 throughout the on and off condition of regulatory MOS-FET 18 during the period of transmitting electric energy from the primary to the secondary side after main MOS-FET 3 is turned off so that such a successive flow serves to reduce the maximum value of first diode current I_{D1} through first diode 4 and thereby lower RMS value of output current. This can decay ripple current appearing in the secondary side and diminish power loss suffered in each secondary output circuit. In addition, lowered RMS value of output current can reduce charging current load on first capacitor 5 to extend service life of first capacitor 5.

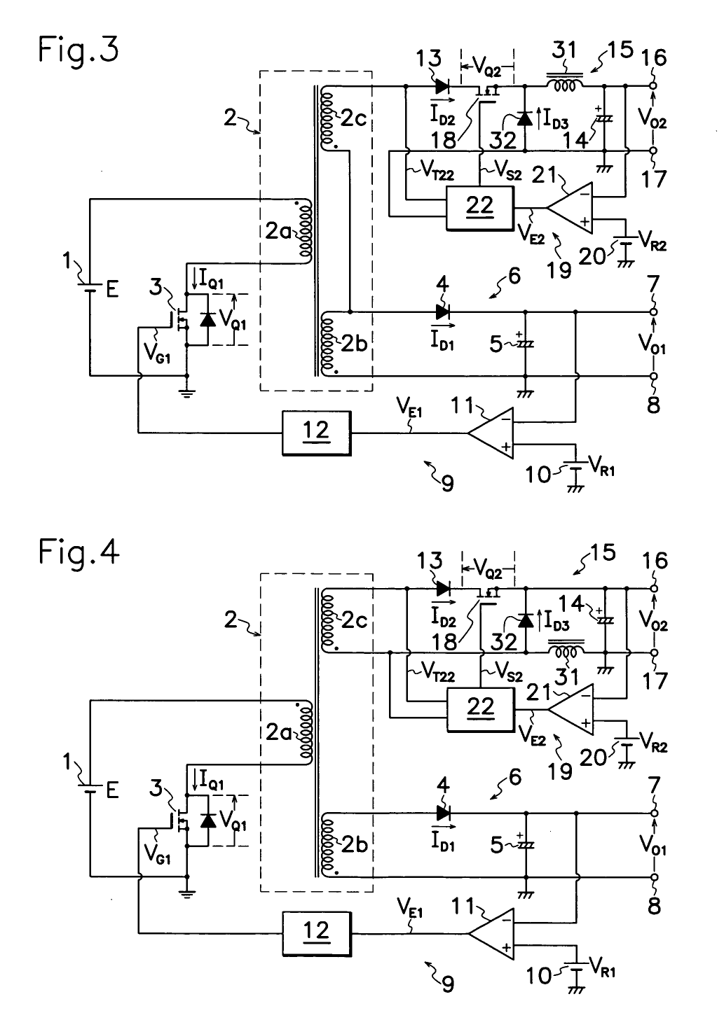

The embodiment of the switching power source device shown in FIG. 1, can be modified in various ways. For example, as shown in FIG. 3, a second embodiment of the switching power source device according to the present invention, comprises a series connection of first and second secondary windings 2b and 2c of transformer 2 to rectify and smooth sum of voltages on first and second secondary windings 2b and 2c through second smoother 15, thereby producing from second output terminals 16 and 17 a second output voltage V_{O2} higher than first output voltage V_{O1}. Moreover, as shown in FIG. 4, a third embodiment of the switching power source device according to the present invention, comprises a reactor 31 connected between a lower end of second secondary winding 2c of transformer 2 and a lower end of second capacitor 14 in lieu of reactor 31 of FIG. 1 connected between an upper end of second secondary winding 2c and an upper end of second capacitor 14. Second and third embodiments shown in FIGS. 3 and 4 demonstrate the functions and effects substantially similar to those of the first embodiment shown in FIG. 1.

First, second and third embodiments shown in FIGS. 1 to 4 are so adapted that regulatory MOS-FET 18 is turned on during the off period of main MOS-FET 3; after the on period is over which is determined by level of output voltage V_{O2} from second smoother 15, regulatory MOS-FET 18 is turned off. Otherwise, these embodiments may be so altered that after main MOS-FET 3 is turned off and also after the standby time is over which is determined by level of output voltage VO₂ from second smoother 15, regulatory MOS-FET 18 is turned on, and upon turning-on of main MOS-FET 3, regulatory MOS-FET 18 is turned off. Specifically, when output voltage V_{O2} from second smoother 15 is of the level lower than the target value, second PWM controller 22 may shorten the standby time from turning-off of main MOS-FET 3 to turning-on of regulatory MOS-FET 18 to extend the on time of regulatory MOS-FET 18 and thereby boost output voltage V_{O2} from second smoother 15. Adversely, when output voltage V_{O2} from second smoother 15 is of the level higher than the target value, second PWM controller 22 may extend the standby time from turning off of main MOS-FET 3 to turning on of regulatory MOS-FET 18 to shorten the on time of regulatory MOS-FET 18 and thereby lower second output voltage V_{O2} from second smoother 15. Also, main MOS-FET 3 is turned on upon turning off of regulatory MOS-FET 18 to invert the polarity of voltages induced on first and second secondary windings 2b and 2c of transformer 2 and thereby apply reversely biased voltage on second diode 13. Accordingly, second diode 13 is brought into deactivation not to apply voltage between drain and source terminals of regulatory MOS-FET 18 for zero volt switching (ZVS) of MOS-FET 18, thereby causing reduced switching loss.

Alternatively, regulatory MOS-FET 18 may be turned on when voltage V_{T22} on either of first and second secondary windings 2b and 2c of transformer 2 reaches substantially zero or negative value, and then, turned off when or after the on time is over which is determined by level of second output voltage V_{O2} from second smoother 15. In other words, electric energy is stored in transformer 2 during the on period of main MOS-FET 3, and discharged from either of first and second secondary windings 2b and 2c during the off period of main MOS-FET 3. Then, when energy release is completed to the extent that voltage V_{T22} on second secondary winding 2c becomes nearly zero, regulatory MOS-FET 18 is turned on. At this moment, source-drain voltage V_{Q2} across regulatory MOS-FET 18 is substantially zero to perform zero volt switching (ZVS) of regulatory MOS-FET 18 for improved switching efficiency. Although there may be produced ringing voltage on each of first and second secondary windings 2b and 2c in some cases, first and second output voltages V_{O1} and V_{O2} from first and second smoothers 6 and 15 never rise due to essentially no or zero residual energy in transformer 2. In addition, when main MOS-FET 3 is turned on while regulatory MOS-FET 18 is kept on, winding current I_{Q1} runs through the primary series circuit including DC power source 1, primary winding 2a of transformer 2 and main MOS-FET 3 to accumulate electric energy in transformer 2, and simultaneously negative voltage occurs on each of first and second secondary windings 2b and 2c to bias first and second diodes 4 and 13 in the opposite direction for their deactivation. Accordingly, no second diode current flows through second diode 13 although regulatory MOS-FET 18 is kept on. Later, when main MOS-FET 3 is turned off, polarity of voltages on first and second secondary windings 2b and 2c of transformer 2 is turned over to thereby apply voltages in the forward direction on first and second rectifying diodes 4 and 13. At this moment, as regulatory MOS-FET 18 has already been turned on, the device can commence synchronous operation of first and second smoothers 6 and 15. Consequently, when second secondary winding 2c produces voltage V_{T22} of zero or negative level, no voltage is applied between drain and source terminals of regulatory MOS-FET 18, and therefore, switching-on of regulatory MOS-FET 18 at this time can provide a zero volt switching to reduce switching loss.

According to the present invention, when output regulatory switching element is turned on during the off period of main switching element, first and second diode currents concurrently flow respectively through first and second secondary windings of transformer to alleviate current convergence in any of secondary windings. Also, during the period for transmitting energy from primary to secondary side of transformer under the off condition of main switching element, output current may continuously move down first secondary winding whether output regulatory switching element is turned on or off, there advantageously causing RMS value of output current to drop and power loss suffered in each of secondary output circuits to decrease. Accordingly, the present invention can provide a highly-efficient, inexpensive, extremely-stable and low-noise switching power source device of multi-output type.

The present invention should not be limited only to the switching power source device of multi-output type having two secondary windings in transformer, but may be applied to ones having three or more secondary windings. The present invention is preferably applicable to switching power source devices of multi-output and flyback type for producing outputs from secondary windings during the off condition of a main switching element.

What is claimed are:

1. A switching power source device of multi-output type comprising:
a primary winding of a transformer and a main switching element connected in series to a DC power source;
a first rectifying smoother connected to a first secondary winding of said transformer;
a second rectifying smoother connected to a second secondary winding of said transformer;
a main control circuit for controlling the on and off operation of said main switching element based on said first rectifying smoother;
a regulatory switching element connected between a smoothing capacitor provided in said second rectifying smoother and said second secondary winding;
a reactor connected in a series circuit of said second secondary winding, regulatory switching element and second rectifying smoother; and
an output controller for controlling the on and off operation of said regulatory switching element based on a voltage applied on said smoothing capacitor of said second rectifying smoother to accumulate electric energy in said transformer during the on period of said main switching element and take out first and second DC outputs respectively from said first and second secondary windings through said first and second rectifying smoothers during the off period of said main switching element.

2. The switching power source device of claim 1, wherein said regulatory switching element is turned on during the off operation of said main switching element, and
the on time of said regulatory switching element is determined by an output voltage level of said second rectifying smoother; and
said regulatory switching element is turned off after said on time has elapsed;
said on time is extended and shortened when output voltage level of said second rectifying smoother is respectively lower and higher than a target voltage value.

3. The switching power source device of claim 1, wherein said regulatory switching element is turned on after said main switching element is turned off and standby time is over which is determined by level of output voltage from said second rectifying smoother;
said regulatory switching element is turned off when said main switching element is turned on;
said standby time is shortened and extended when output voltage level of said second rectifying smoother is respectively lower and higher than a target voltage value.

4. The switching power source device of claim 1, wherein said output regulatory switching element is turned on when any of said secondary windings of said transformer produces voltage of substantially zero or negative potential;
said output regulatory switching element is turned off when on period is over which is determined by level of output voltage from said second rectifying smoother;
said on time is extended and shortened when output voltage level of said second rectifying smoother is respectively lower and higher than a target voltage value.

5. The switching power source device of claim 1, further comprising a smoothing capacitor provided in said second rectifying smoother; and
a recovery rectifying element connected between said reactor and smoothing capacitor for regenerating electric energy accumulated in said reactor as an output.
